(19) United States
(12) Patent Application Publication
(10) Pub. No.: US 2026/0291285 A1
(43) Pub. Date: Sep. 24, 2026

(54) POWER RECEIVING DEVICE

(71) Applicant: TOYODA GOSEI CO., LTD., Kiyosu-shi (JP)

(72) Inventors: Yuki TOKUYAMA, Kiyosu-shi (JP); Atsushi SUGIHARA, Kiyosu-shi (JP); Seigi SHIMIZU, Kiyosu-shi (JP); Shinichiro FUKI, Kiyosu-shi (JP)

(21) Appl. No.: 19/545,299

(22) Filed: Feb. 20, 2026

(30) Foreign Application Priority Data
Mar. 21, 2025 (JP) 2025-047133

(51) Int. Cl. H02J 50/00; H02J 50/20; H05K 1/02

(52) U.S. Cl. CPC H02J 50/005; H02J 50/20; H05K 1/0243; H05K 2201/10098

(57) ABSTRACT

A power receiving device that is mounted inside a housing and used in a wireless power transmission system. The power receiving device incudes an antenna element of a microstrip antenna, an RF line to transmit a power transmission wave received by the antenna element, a rectifier IC that converts the power transmission wave transmitted through the RF line into DC power, and a circuit board which includes a GND layer therein and on which the antenna element, the RF line and the rectifier IC are provided. A hold space is provided on a surface of the circuit board on which the RF line is provided, the hold space being provided so as not to overlap with the RF line and, when the power receiving device is mounted inside the housing, coming into contact with a holding portion that is included in the housing to hold the power receiving device.

### CROSS-REFERENCE TO RELATED APPLICATIONS

The present patent application claims the priority of Japanese patent application No. 2025/047133 filed on Mar. 21, 2025, and the entire contents of Japanese patent application No. 2025/047133 are hereby incorporated by reference.

### TECHNICAL FIELD

The present invention relates to a power receiving device.

### BACKGROUND ART

Various mechanisms to mount a circuit board onto another component are known (see, e.g., Patent Literature 1). Patent Literature 1 discloses a latch mechanism that fixes a module substrate in a state of being inserted into a connector provided on another substrate.

### CITATION LIST

### Patent Literature

Patent Literature 1: JP H9/266389 A

### SUMMARY OF INVENTION

Generally, circuit boards are designed so that wirings do not overlap portions with which other components come into contact when the circuit boards are mounted. However, in circuit boards used for wireless power transmission systems, the antenna gain is affected by the dielectric constant of housings, etc. in which circuit boards are mounted. Therefore, the desired characteristics may not be obtained by simply designing so that wirings do not overlap portions with which other components come into contact.

It is an object of the invention to provide a power receiving device which is used in a wireless power transmission system and has an antenna on a circuit board and in which a decrease in antenna gain due to the dielectric constant of a housing in which the power receiving device is mounted is suppressed.

One aspect of the invention provides the following power receiving device.

(1) A power receiving device that is mounted inside a housing and used in a wireless power transmission system, the power receiving device comprising:

an antenna element of a microstrip antenna that receives a power transmission wave;

an RF line to transmit the power transmission wave received by the antenna element;

a rectifier IC that converts the power transmission wave transmitted through the RF line into DC power; and

a circuit board which comprises a GND layer therein and on which the antenna element, the RF line and the rectifier IC are provided,

wherein a hold space is provided on a surface of the circuit board on which the RF line is provided, the hold space being provided so as not to overlap with the RF line and, when the power receiving device is mounted inside the housing, coming into contact with a holding portion that is included in the housing to hold the power receiving device.

(2) The power receiving device as defined in (1), wherein the RF line is located at a position on the inner side of the hold space in a short side direction of the circuit board.

(3) The power receiving device as defined in (1) or (2), wherein the antenna element is located at a position on the inner side of the hold space in the short side direction of the circuit board.

(4) The power receiving device as defined in (1) or (2), wherein the hold space is provided along an edge of the circuit board in a long side direction.

(5) The power receiving device as defined in (1) or (2), wherein the planar shape of the circuit board is rectangular or elliptical, wherein a plurality of the antenna elements are arranged along the long side direction or major axis direction of the circuit board, wherein a notch used for alignment when mounting the power receiving device inside the housing is formed on a side surface of the circuit board extending in the long side direction or the major axis direction, and wherein the notch does not overlap with the plurality of the antenna elements in terms of position in the long side direction or the major axis direction of the circuit board.

(6) The power receiving device as defined in (1) or (2), wherein the antenna element is provided on a surface of the circuit board different from the surface on which the RF line is provided.

(7) The power receiving device as defined in (6), wherein a recess used for alignment when mounting the power receiving device inside the housing is provided on a surface of the circuit board different from the surface on which the antenna element is provided, and wherein the recess does not penetrate at least one of the GND layers provided inside the circuit board.

### ADVANTAGEOUS EFFECTS OF INVENTION

According to an embodiment of the invention, it is possible to provide a power receiving device which is used in a wireless power transmission system and has an antenna on a circuit board and in which a decrease in antenna gain due to the dielectric constant of a housing in which the power receiving device is mounted is suppressed.

### BRIEF DESCRIPTION OF DRAWINGS

FIG. 1A is a top view showing a power receiving device in an embodiment of the present invention.

FIG. 1B is a bottom view showing the power receiving device.

FIG. 2 is a cross-sectional view showing the power receiving device taken along the thickness direction.

FIG. 3 is a block diagram illustrating a configuration of the power receiving device 1.

FIG. 4 is a bottom view of the power receiving device 1, showing an example arrangement of the main wiring and holding spaces.

FIG. 5A is a schematic perspective view showing a configuration of a wirelessly-chargeable device in which the power receiving device is mounted.

FIG. 5B is a schematic cross-sectional view showing the wirelessly-chargeable device.

FIGS. 6A to 6C are plan views showing examples of the planar shapes of circuit boards and examples of the positions of notches formed on the respective circuit boards.

FIGS. 7A and 7B are plan views showing examples of the planar shapes of circuit boards and examples of the positions of notches formed on the respective circuit boards.

FIG. 8A is a plan view showing the power receiving device having recesses on the circuit board.

FIG. 8B is a cross-sectional view showing the power receiving device.

### DESCRIPTION OF EMBODIMENTS

### Configuration of a power receiving device

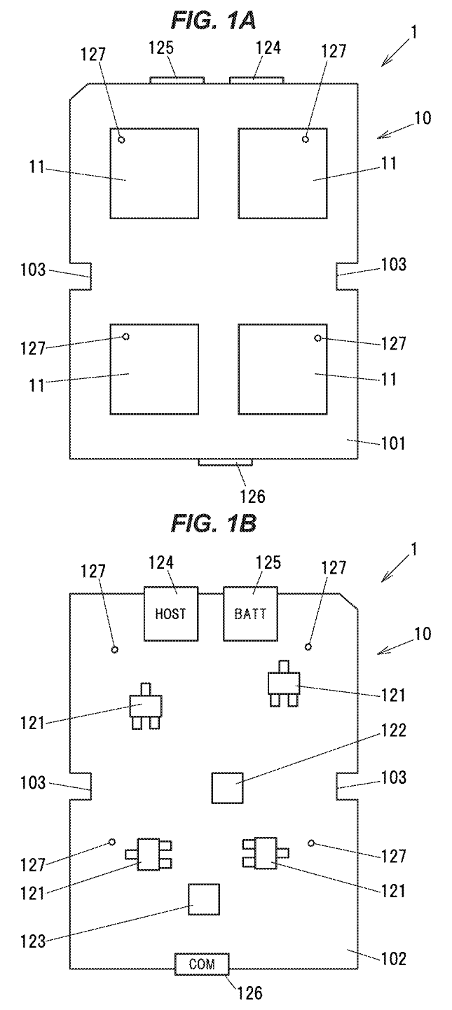

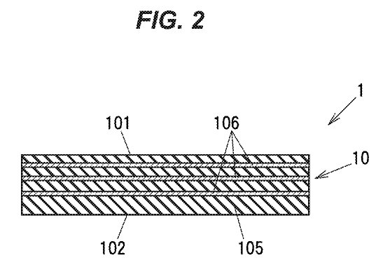

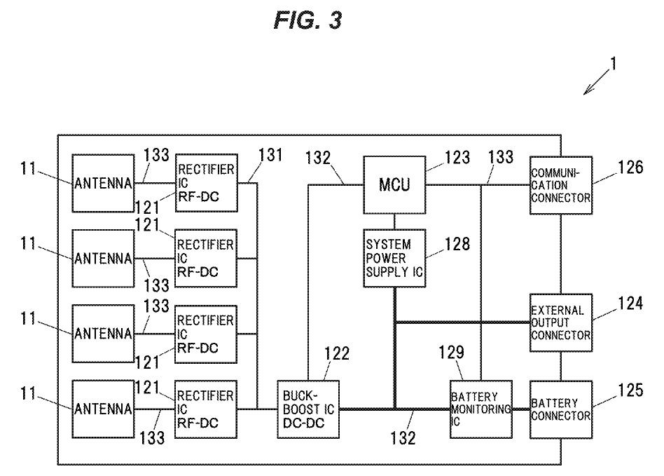

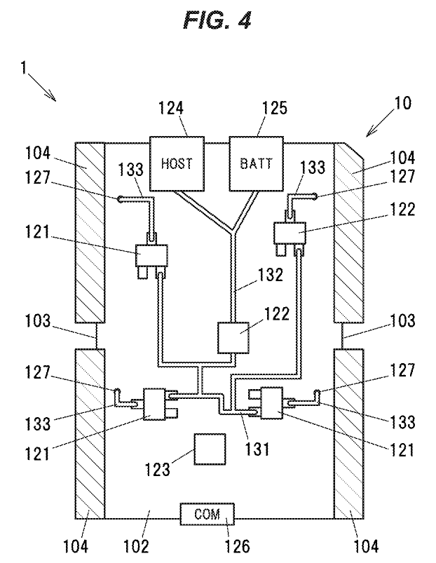

FIGS. 1A and 1B are a top view and a bottom view showing a power receiving device 1 in an embodiment of the invention. FIG. 2 is a cross-sectional view showing the power receiving device 1 taken along the thickness direction. FIG. 3 is a block diagram illustrating a configuration of the power receiving device 1. FIG. 4 is a bottom view of the power receiving device 1, showing an example arrangement of the main wiring and holding spaces.

The power receiving device 1 is a power receiving device mounted inside a housing and used in a wireless power transmission system that uses power transmission waves such as microwaves.

The power receiving device 1 includes antenna elements 11 of a microstrip antenna that receives power transmission waves, rectifier ICs 121 that convert the power transmission waves received by the antenna elements 11 into DC power, RF lines 133 to transmit the power transmission waves output from the antenna elements 11 to the rectifier ICs 121, and a circuit board 10 which has GND layers 106 therein and on which the antenna elements 11, the RF lines 133 and the rectifier ICs 121 are provided.

In the example shown in FIGS. 1A and 1B, the antenna elements 11 are provided on a first surface 101 of the circuit board 10, and the RF lines 133 and the rectifier ICs 121 are provided on a second surface 102 of the circuit board 10 on the opposite side to the first surface 101.

In addition, hold spaces 104 are provided on the surface of the circuit board 10 on which the RF lines 133 are provided, i.e., on the second surface 102, so as not to overlap with the RF lines 133.

The hold spaces 104 are a region (i.e., contact region or mounting region) which comes into contact with a portion of a housing (a holding portion 201 described later) when the power receiving device 1 is mounted inside the housing. In FIG. 4, the locations of the hold spaces 104 on the second surface 102 are indicated by hatching. The hold spaces 104 are provided, e.g., at the four corners of the second surface 102, as shown in FIG. 4.

The antenna elements 11 may be provided on the second surface 102 of the circuit board 10 in the similar manner to the RF lines 133, but providing the antenna elements 11 on a surface different from that with the RF lines 133, i.e., on the first surface 101 increases the degree of freedom in arranging the antenna elements 11 and the RF lines 133.

The antenna elements 11 on the first surface 101 are connected to the RF lines 133 on the second surface 102 through vias 127 that penetrate the circuit board 10 in the thickness direction.

The antenna element 11 is formed of, e.g., a thin film of a conductive metal such as copper. The planar shape of the antenna element 11 is, e.g., rectangular. The planar shape, number, and arrangement of the antenna elements 11 are not particularly limited and can be appropriately set according to, e.g., the planar shape or area of the circuit board 10.

In addition, the planar shape and area of the circuit board 10 are not particularly limited and can be appropriately set according to, e.g., the shape or size of the internal space of the housing in which the power receiving device 1 is mounted.

As shown in FIG. 2, the circuit board 10 has a base 105 made of an insulating material, and the GND layers 106 sandwiched from above and below by the base 105. The GND layers 106 and the antenna elements 11 are arranged parallel to each other. The circuit board 10 may include plural GND layers 106 as shown in FIG. 2, or may include a single GND layer 106. The GND layer 106 typically has the same planar shape and area as the circuit board 10. In FIG. 2, elements and wiring provided on the first surface 101 and the second surface 102 are omitted.

On the second surface 102, the circuit board 10 also includes a DC line 131 to transmit DC power output from the rectifier ICs 121 to a boost IC 122, the boost IC 122 that outputs the DC power transmitted through the DC line 131 as DC power with a higher voltage, a power supply line 132 to transmit the DC power boosted by the boost IC 122 to an external device connector 124 and a battery connector 125, the external device connector 124 for connection of a cable connected to an external device such as an external board, the battery connector 125 for connection of a cable connected to a battery, and a control MCU 123 that controls operation of each IC on the circuit board 10 based on a control signal transmitted from external equipment through a communication connector 126.

In addition, on the second surface 102, the circuit board also includes a system power supply IC 128 that supplies power for operation of the control MCU 123, and a battery monitoring IC 129 that monitors the state of the battery connected to the battery connector 125, such as degradation, temperature, discharge rate, charging status, and remaining battery capacity.

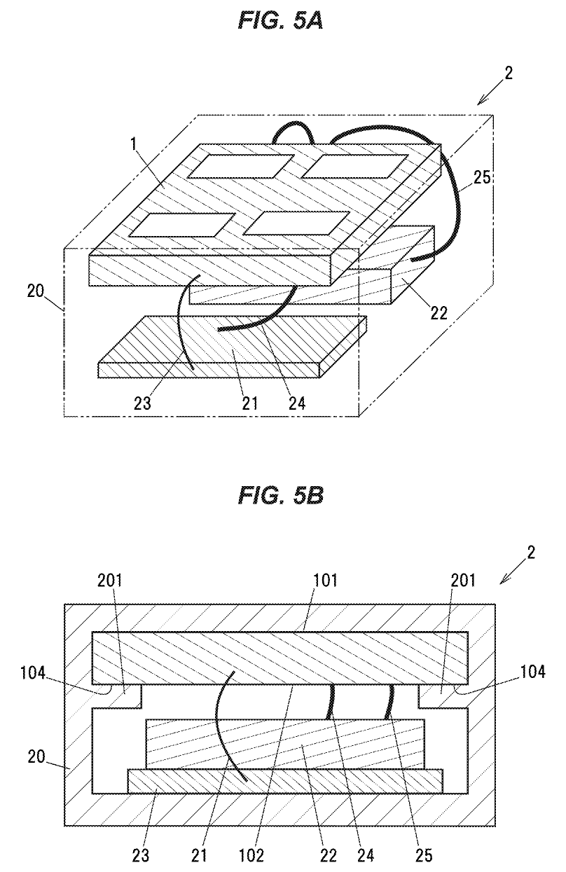

FIGS. 5A and 5B are a perspective view and a cross-sectional view schematically showing the configuration of a wirelessly-chargeable electronic device 2 in which the power receiving device 1 is mounted. The electronic device 2 is, e.g., a smartphone, a tablet device, a personal computer, a drone, a remote control, a power bank (including other secondary batteries), an electronic key, and a mouse (a computer input device), etc.

The electronic device 2 includes the power receiving device 1, a substrate 21, and a battery 22 inside a housing 20. The substrate 21 is connected to the external device connector 124 and the communication connector 126 of the power receiving device 1 respectively through a cable 23 and a cable 24, and has a function of controlling operation of the power receiving device 1 while receiving power supply. The battery 22 is connected to the battery connector 125 of the power receiving device 1 through a cable 25 and stores DC power transmitted from the power receiving device 1 through the cable 25. The external device connector 124 and the communication connector 126 of the power receiving device 1 may be integrated into one connector and connected to the substrate 21 through a single cable that serves as the cable 23 as well as the cable 24.

The housing 20 holds the power receiving device 1 therein by means of the holding portions 201 included in the housing 20. The holding portions 201 come into contact with the hold spaces 104 of the circuit board 10 of the power receiving device 1. The holding portion 201 may be a portion formed integrally with a main body (outer shell portion) of the housing 20, or may be a component attached to the main body. The main body and holding portions 201 of the housing 20 are typically made of resin.

To hold the power receiving device 1 by the housing 20, a holding portion included in the housing 20 also comes into contact with the entire first surface 101 or a portion of the first surface 101. In the example shown in FIG. 5B, an inner surface of the housing 20 serves as the holding portion for the first surface 101 and is in contact with the entire first surface 101. If necessary, to suppress a decrease in gain due to contact of the first surface 101 having the antenna elements 11 thereon with the housing 20, the holding portion of the housing 20 may be in contact with only a portion of the first surface 101 and a space may be provided between the housing 20 and the first surface 101.

As described above, the hold spaces 104 do not overlap with the RF lines 133 on the second surface 102 of the circuit board 10. Therefore, when the power receiving device 1 is mounted inside the housing 20, the holding portions 201 of the housing 20 do not come into contact with the RF lines 133 on the circuit board 10. This ensures that a certain distance is provided between the RF lines 133 and the holding portions 201, which suppresses a decrease in the antenna gain of the power receiving device 1 caused by the influence of the conductivity of the housing 20.

Then, when the planar shape of the circuit board 10 is rectangular, it is preferable that the RF lines 133 be located at positions on the inner side of the hold spaces 104 in the short side direction of the circuit board 10 (the horizontal direction in FIG. 4), as shown in FIG. 4. In this case, it is easy to increase the distance between the RF lines 133 and the holding portions 201, hence, the decrease in the antenna gain of the power receiving device 1 caused by the influence of the conductivity of the housing 20 can be suppressed more effectively.

In addition, when the planar shape of the circuit board 10 is rectangular, it is preferable that the antenna elements 11 be located at positions on the inner side of the hold spaces 104 in the short side direction of the circuit board 10. By ensuring that a certain distance is provided between the antenna elements 11 and the holding portions 201, the decrease in the antenna gain of the receiving device 1 caused by the influence of the conductivity of the housing 20 can be suppressed more effectively.

In addition, when the planar shape of the circuit board 10 is rectangular, it is preferable that the hold spaces 104 be provided along the edges extending in the long side direction of the circuit board 10 (the vertical direction in FIG. 4), as shown in FIG. 4. In this case, compared to the case where the hold spaces 104 are arranged along the edges extending in the short side direction of the circuit board 10, the holding portions 201 can stably hold the circuit board 10 when the power receiving device 1 is mounted in the housing 20 and it is also easier to suppress warping of the circuit board 10.

As shown in FIGS. 1 and 4, the circuit board 10 may have notches 103 on its sides, which are used for alignment when mounting the power receiving device 1 inside the housing 20. When mounting the power receiving device 1 inside the housing 20, protrusions which are provided on the housing 20 so as to conform to the notches 103 are fitted into the notches 103, allowing for alignment of the power receiving device 1. In addition, by using the notches 103, the power receiving device 1 can be stably mounted in the housing 20 even when the size of the power receiving device 1 is large.

When the planar shape of the circuit board 10 is rectangular and plural antenna elements 11 are arranged along the long side direction of the circuit board 10, it is preferable that the notches 103 be formed on the side surfaces extending in the long side direction of the circuit board 10 and do not overlap with the plural antenna elements 11 in the terms of position in the long side direction of the circuit board 10. In this case, it is possible to ensure that a large distance is provided between the notches 103 and the antenna elements 11.

Similarly, when the planar shape of the circuit board 10 is elliptical and plural antenna elements 11 are arranged along the major axis direction of the circuit board 10, it is preferable that the notches 103 be formed on the side surfaces extending in the major axis direction of the circuit board 10 and do not overlap with the plural antenna elements 11 in terms of position in the major axis direction of the circuit board 10. In this case, it is possible to ensure that a large distance is provided between the notches 103 and the antenna elements 11.

In the portion of the circuit board 10 where the notches 103 are formed, the GND layers 106 provided inside the circuit board 10 are missing, hence, the antenna gain decreases if the notches 103 are located near the antenna elements 11. Therefore, the decrease in the antenna gain can be suppressed by ensuring that a large distance is provided between the notches 103 and the antenna elements 11.

In addition, it is preferable that the notch 103 be provided in the middle between two adjacent antenna elements 11 among the plural antenna elements 11 arranged along the long side or major axis direction of the circuit board 10, in terms of position in the long side or long axis direction of the circuit board 10. In this case, it is easy to increase the distance between the notches 103 and the antenna elements 11, hence, the decrease in the antenna gain of the power receiving device 1 caused by the notches 103 can be suppressed more effectively.

For example, in the example shown in FIGS. 1A and 1B, in terms of position in the long side direction of the circuit board 10, each notch 103 is formed in the middle between two antenna elements 11 arranged side by side along the long side direction of the circuit board 10, thereby effectively suppressing the decrease in the antenna gain of the power receiving device 1 caused by the notches 103.

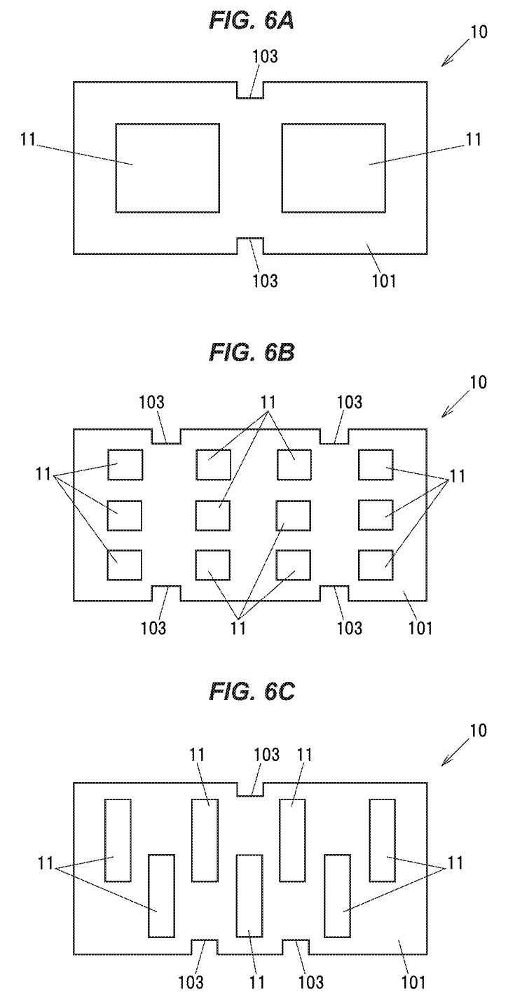

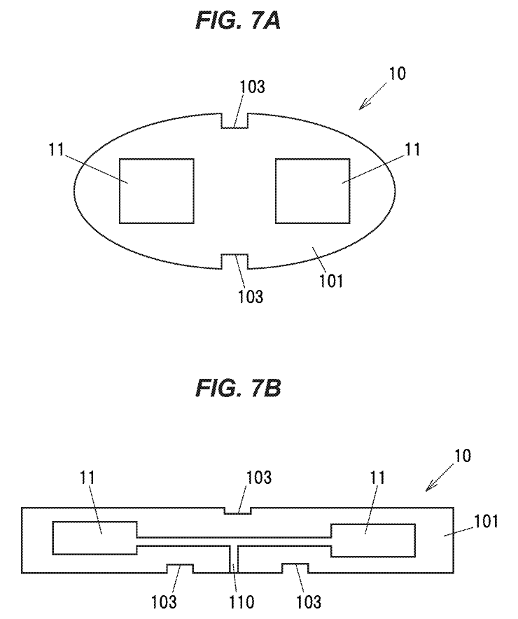

FIGS. 6A to 6C, 7A and 7B are plan views showing examples of the planar shapes of the circuit boards 10 and examples of the positions of the notches 103 formed on the respective circuit boards 10.

In the example shown in FIG. 6A, the planar shape of the circuit board 10 is rectangular, and in terms of position in the long side direction of the circuit board 10 (the horizontal direction in FIG. 6A), the notches 103 are formed in the middle between two antenna elements 11 arranged side by side along the long side direction of the circuit board 10.

In the example shown in FIG. 6B, the planar shape of the circuit board 10 is rectangular, and in terms of position in the long side direction of the circuit board 10 (the horizontal direction in FIG. 6B), the notches 103 are formed in the middle between the first and second antenna elements 11 from the left among the four antenna elements 11 arranged side by side along the long side direction of the circuit board 10 and in the middle between third and fourth antenna elements 11 from the left.

In the example shown in FIG. 6C, the planar shape of the circuit board 10 is rectangular, and in terms of position in the long side direction of the circuit board 10 (the horizontal direction in FIG. 6C), the notches 103 overlap with the plural antenna elements 11 arranged side by side along the long side direction of the circuit board 10. However, in terms of position in the long side direction of the circuit board 10, each notch 103 is located in the middle between two antenna elements 11 closest thereto. Therefore, it is possible to ensure that a certain distance is provided between the notches 103 and the antenna elements 11, which can suppress the decrease in the antenna gain of the power receiving device 1 caused by the notches 103.

In the example shown in FIG. 7A, the planar shape of the circuit board 10 is elliptical, and in terms of position in the major axis direction of the circuit board 10 (the horizontal direction in FIG. 7A), the notches 103 are formed in the middle between two antenna elements 11 arranged side by side along the major axis direction of the circuit board 10.

In the example shown in FIG. 7B, the planar shape of the circuit board 10 is rectangular, and wiring 110 extending from the antenna elements 11 is provided on the first surface 101 on which the antenna elements 11 are provided. Each notch 103 is formed so as not to come into contact with the wiring 110 and, in terms of position in the long side direction of the circuit board 10 (the horizontal direction in FIG. 7B), so as not to overlap with two antenna elements 11 arranged side by side along the long side direction of the circuit board 10.

The notch 103 is preferably formed such that its width along the side of the circuit board 10 is greater than its depth in the direction toward the center of the circuit board 10. By reducing the depth of the notches 103, it is easier to ensure that a distance is provided between the RF lines 133 and the protrusions on the housing 20 that fit into the notches 103 when the power receiving device 1 is mounted in the housing 20, and it is possible to suppress the decrease in the antenna gain of the power receiving device 1 caused by the influence of the conductivity of the housing 20.

It is preferable that the depth and width of the notch 103 be respectively not more than 3 mm and not more than 4 mm. By reducing the area of the notches 103, it is possible to reduce the missing amount of the GND layer 106 provided inside the circuit board 10, thereby suppressing the decrease in the antenna gain of the power receiving device 1.

The notches 103 and the hold spaces 104 are preferably provided at positions that are point-symmetric or line-symmetric with respect to the center point or line of the circuit board 10, as shown in FIG. 4. In this case, the effect of the installation orientation of the power receiving device 1 on the antenna gain can be suppressed. Therefore, after the power receiving device 1 is mounted in the housing 20, the user does not need to pay attention for the orientation of the power receiving device 1.

When the planar shape of the circuit board 10 is rectangular and the hold spaces 104 are provided along the edges of the circuit board 10 extending in the long side direction, it is preferable that the external device connector 124, the battery connector 125 and the communication connector 126 be provided on the short sides of the circuit board 10, as shown in FIG. 4. In this case, it is possible to avoid contact of the external device connector 124, the battery connector 125 and the communication connector 126 with the holding portions 201 when the power receiving device 1 is mounted in the housing 20.

It is preferable that the communication connector 126 be provided on a surface different from that with the antenna elements 11. In this case, the distance between the communication connector 126 and the antenna elements 11 is longer than when the communication connector 126 is provided on the same surface as the antenna elements 11, and the GND layers 106 are located between the communication connector 126 and the antenna elements 11, hence, noise in the communication signal is suppressed. In addition, by placing the communication connector 126 on a different surface from that with the antenna elements 11, it is possible to ensure that a large space is provided for wiring the cable 24 extending from the communication connector 126, which increases the degree of freedom in design of the wiring space on the communication connector 126 side and thereby improves routing flexibility of the cable 24.

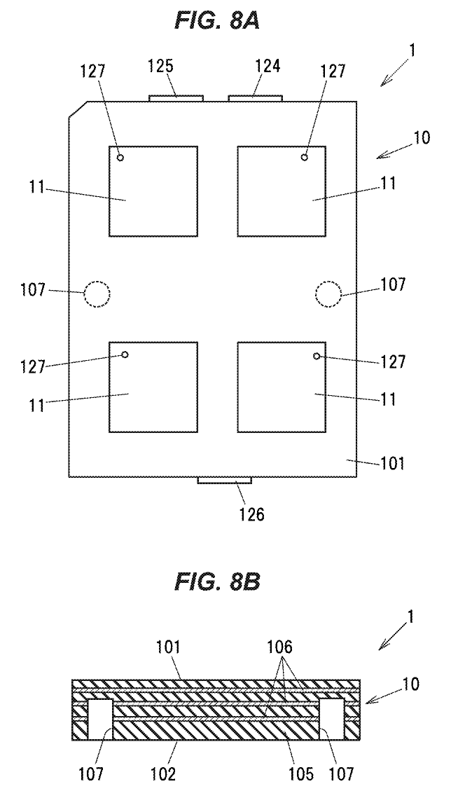

FIGS. 8A and 8B are a plan view and a cross-sectional view showing the power receiving device 1 having recesses 107 on the circuit board 10. The recesses 107 are used for alignment when mounting the power receiving device 1 inside the housing 20, in the similar manner to the notches 103. When mounting the power receiving device 1 inside the housing 20, the protrusions provided on the housing 20 so as to conform to the recesses 107 are fitted into the recesses 107, allowing for alignment of the power receiving device 1.

FIG. 8A is a plan view showing the power receiving device 1 as viewed from the first surface 101 side of the circuit board 10, with the positions of the recesses 107 indicated by dashed lines. When the antenna elements 11 are provided on the first surface 101, the recesses 107 are provided on the second surface 102 so as to avoid various elements and wiring.

Even when the size of the housing 20 is small and it is difficult to provide on the inner side of the housing 20 the protrusions to conform to the notches 103 on the sides of the circuit board 10, the power receiving device 1 can be aligned using the recesses 107 instead of the notches 103.

The recesses 107 are preferably provided so as not to penetrate at least one of the GND layers 106 provided inside the circuit board 10. In this case, since at least one GND layer 106 can avoid having a missing portion, the decrease in the antenna gain of the power receiving device 1 caused by providing the recesses 107 can be suppressed.

When, e.g., one GND layer 106 is provided inside the circuit board 10, the recesses 107 are preferably provided so as not to penetrate this one GND layer 106. Then, when plural GND layers 106 are provided inside the circuit board 10, the recesses 107 are preferably provided so as not to penetrate at least the GND layer 106 closest to the first surface 101 on which the antenna elements 11 are provided, as shown in FIG. 8B.

### Effects of the embodiment

In the power receiving device 1 in the embodiment of the invention, a decrease in antenna gain can be suppressed by providing the hold spaces 104 at a position where the influence of the dielectric constant of the housing 20 in which the power receiving device 1 is mounted is suppressed.

Although the embodiment of the invention has been described, the invention is not intended to be limited to the embodiment, and the various kinds of modifications can be implemented without departing from the gist of the invention. In addition, the constituent elements in the embodiment can be arbitrarily combined without departing from the gist of the invention. In addition, the invention according to claims is not to be limited to the above-mentioned embodiment. Further, please note that not all combinations of the features described in the embodiment are necessary to solve the problem of the invention.

### REFERENCE SIGNS LIST

1 POWER RECEIVING DEVICE

10 CIRCUIT BOARD

103 NOTCH

104 HOLD SPACE

106 GND LAYER

107 RECESS

11 ANTENNA ELEMENT

121 RECTIFIER IC

133 RF LINE

20 HOUSING

201 HOLDING PORTION

1. A power receiving device that is mounted inside a housing and used in a wireless power transmission system, the power receiving device comprising:
an antenna element of a microstrip antenna that receives a power transmission wave;
an RF line to transmit the power transmission wave received by the antenna element;
a rectifier IC that converts the power transmission wave transmitted through the RF line into DC power; and
a circuit board which comprises a GND layer therein and on which the antenna element, the RF line and the rectifier IC are provided,
wherein a hold space is provided on a surface of the circuit board on which the RF line is provided, the hold space being provided so as not to overlap with the RF line and, when the power receiving device is mounted inside the housing, coming into contact with a holding portion that is included in the housing to hold the power receiving device.

2. The power receiving device according to claim 1, wherein the RF line is located at a position on the inner side of the hold space in a short side direction of the circuit board.

3. The power receiving device according to claim 1, wherein the antenna element is located at a position on the inner side of the hold space in the short side direction of the circuit board.

4. The power receiving device according to claim 1, wherein the hold space is provided along an edge of the circuit board in a long side direction.

5. The power receiving device according to claim 1, wherein the planar shape of the circuit board is rectangular or elliptical, wherein a plurality of the antenna elements are arranged along the long side direction or major axis direction of the circuit board, wherein a notch used for alignment when mounting the power receiving device inside the housing is formed on a side surface of the circuit board extending in the long side direction or the major axis direction, and wherein the notch does not overlap with the plurality of the antenna elements in terms of position in the long side direction or the major axis direction of the circuit board.

6. The power receiving device according to claim 1, wherein the antenna element is provided on a surface of the circuit board different from the surface on which the RF line is provided.

7. The power receiving device according to claim 6, wherein a recess used for alignment when mounting the power receiving device inside the housing is provided on a surface of the circuit board different from the surface on which the antenna element is provided, and wherein the recess does not penetrate at least one of the GND layers provided inside the circuit board.
